(19) United States
(12) Patent Application Publication
(10) Pub. No.: US 2013/0300260 A1
(43) Pub. Date: Nov. 14, 2013

(54) Piezoelectric Device

(71) Applicant: Siward Crystal Technology Co., Ltd., Taichung City (TW)

(72) Inventor: Ping-Feng Liu, Taichung City (TW)

(21) Appl. No.: 13/888,411

(22) Filed: May 7, 2013

(30) Foreign Application Priority Data
May 10, 2012 (TW) 101116681

(51) Int. Cl. H01L 41/053

(52) U.S. Cl. CPC H01L 41/053
USPC 310/344; 310/348

(57) ABSTRACT

A piezoelectric device includes: a base having a top surface, and first and second marginal ends; first and second supporting stands protruding from the top surface of the base; an adhesive applied to and filled between the first and second supporting stands; and a piezoelectric resonator including a mounting part having outer and inner sections respectively bonded to the first and second supporting stands, and a middle section bonded to the adhesive, and a resonant arm extending from the inner section toward the second marginal end in a cantilever fashion.

### CROSS-REFERENCE TO RELATED APPLICATION

This application claims priority of Taiwanese application no. 101116681, filed on May 10, 2012.

### BACKGROUND OF THE INVENTION

1. Field of the Invention

This invention relates to a piezoelectric device.

2. Description of the Related Art

As shown in FIG. 4, US Patent Application Publication No. 2002/0113523 A1 discloses a conventional piezoelectric device that comprises a base 1, a cover 2 sealingly mounted to the base 1 so as to define an inner space between the base 1 and the cover 2, and a piezoelectric resonator 3 disposed in the inner space. The base 1 has a top surface 101 and a supporting stand 102 disposed on the top surface 101. The piezoelectric resonator 3 has a mounting part 301, and a pair of spaced apart resonant arms 302 only one is shown extending parallel to the top surface 101 and from the mounting part 301. The mounting part 301 is adhered to the supporting stand 102 by an adhesive 4. The piezoelectric resonator 3 of the piezoelectric device can resonate at a predetermined frequency when an external voltage is applied to the piezoelectric device.

However, in the conventional piezoelectric device, since connection strength between the supporting stand 102 and the piezoelectric resonator 3 is relatively weak, separation of the piezoelectric resonator 3 from the supporting stand 102 might occur. Moreover, if the piezoelectric device is chopped, free ends of the resonant arms 302 of the piezoelectric resonator 3 might collide with the top surface 101 of the base 1 and thus, the piezoelectric resonator 3 might be deformed, thereby resulting in malfunction of the piezoelectric device.

### SUMMARY OF THE INVENTION

Therefore, an object of the present invention is to provide a piezoelectric device that can overcome at least one of the aforesaid drawbacks associated with the prior art.

Accordingly, a piezoelectric device of this invention includes:

a base having a top surface, and first and second marginal ends that are oppositely disposed;

a first supporting stand protruding from the top surface of the base;

a second supporting stand protruding from the top surface of the base and spaced apart from the first supporting stand;

an adhesive applied to upper surfaces of the first and second supporting stands and filled between the first and second supporting stands; and

a piezoelectric resonator including amounting part which has an outer section adhesively bonded to the upper surface of the first supporting stand, an inner section adhesively bonded to the upper surface of the second supporting stand, and a middle section disposed between the outer and inner sections and bonded to a top surface of the adhesive, and a resonant arm extending from the inner section toward the second marginal end in a cantilever fashion.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a cross-sectional view of the first preferred embodiment of a piezoelectric device according to this invention;

FIG. 2 is a cross-sectional view taken along line II-II in FIG. 1;

FIG. 3 is a cross-sectional view of the second preferred embodiment of a piezoelectric device according to this invention; and

FIG. 4 is a cross-sectional view of a conventional piezoelectric device.

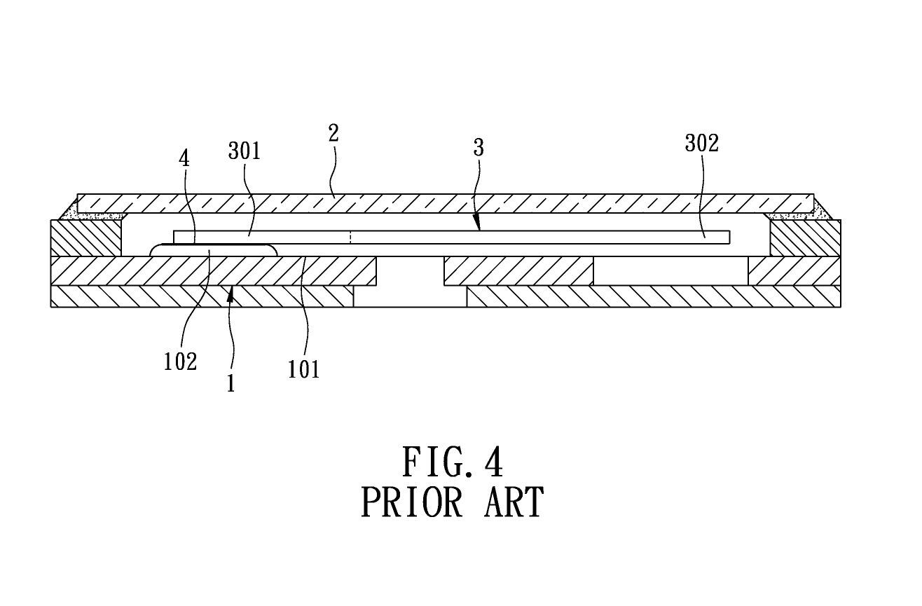

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

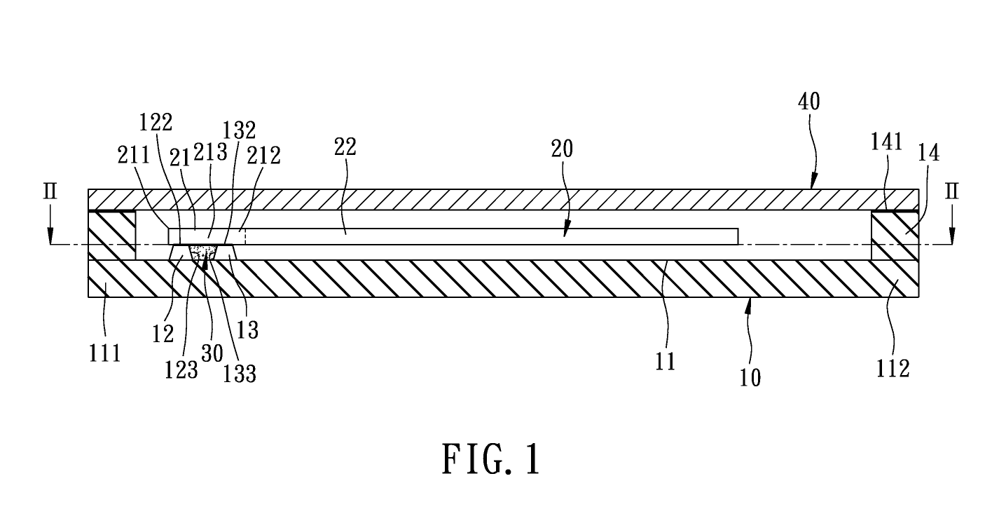

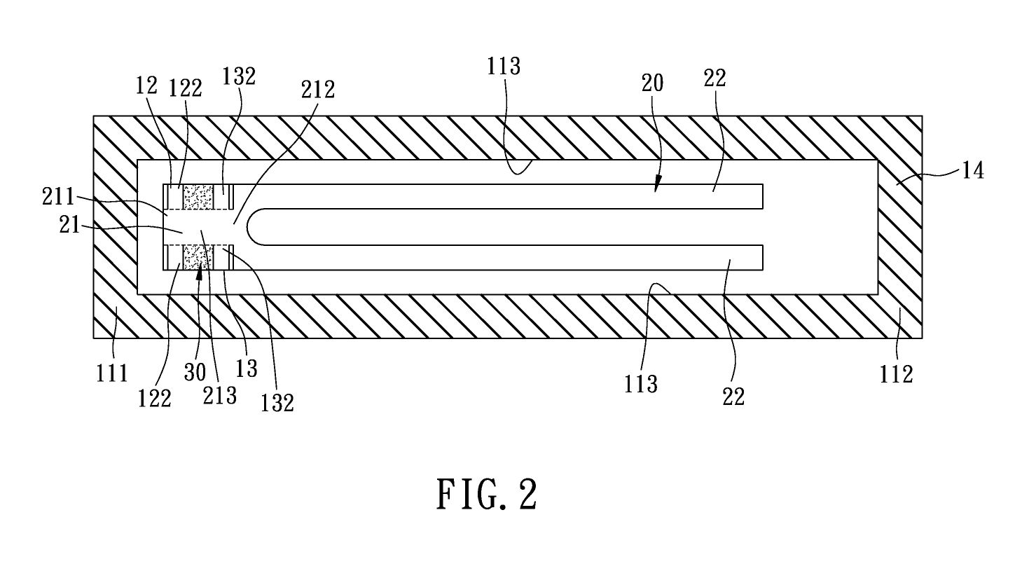

Referring to FIGS. 1 and 2, the piezoelectric device of the first preferred embodiment according to this invention comprises a base 10, first and second supporting stands 12, 13, a piezoelectric resonator 20 made of quartz, an adhesive 30, and a cover 40.

The base 10 is made of ceramic in this embodiment, and has a top surface 11 which has first and second marginal ends 111, 112 that are oppositely disposed. The top surface 11 of the base 10 further has a pair of longitudinal marginal ends 113 each interconnecting the first and second marginal ends 111, 112.

The base 10 further has a surrounding wall 14 extending upwardly from the first and second marginal ends 111, 112 and the longitudinal marginal ends 113 of the top surface 11 of the base 10. The surrounding wall 14 and the top surface 11 of the base 10 cooperatively define an inner space.

The first and second supporting stands 12, 13 protrude from the top surface 11 of the base 10, and are disposed between the first and second marginal ends 111, 112 and between the pair of longitudinal marginal ends 113. The second supporting stand 13 is disposed between and spaced apart from the first supporting stand 12 and the second marginal end 112. In this embodiment, a distance between the first and second supporting stands 12, 13 is shorter than that between the second supporting stand 13 and the second marginal end 112.

The piezoelectric resonator 20 includes a mounting part 21 and a resonant arm 22. The mounting part 21 has outer and inner sections 211, 212 respectively bonded to the first and second supporting stands 12, 13 by the adhesive 30, and a middle section 213 disposed between the outer and inner sections 211 212 and bonded to a top surface of the adhesive 30. The resonant arm 22 extends from the inner section 212 toward the second marginal end 112 in a cantilever fashion. Preferably, the resonant arm 22 is a forked arm.

Specifically, the first supporting stand 12 has a first upper surface 122 bonded to the outer section 211 of the mounting part 21 by the adhesive 30, and a first inner surface 123 bonded to the adhesive 30. The second supporting stand 13 has an upper surface 132 bonded to the inner section 212 of the mounting part 21 by the adhesive 30, and a second inner surface 133 bonded to the adhesive 30. The top surface 11 of the base 10 between the first and second supporting stands 12, 13 is bonded to a bottom surface of the adhesive 30. That is, the adhesive 30 is applied to the upper surfaces 122, 132 of the first and second supporting stands 12, 13 and filled between the first and second supporting stands 12, 13. In this embodiment, the upper surface 122 of the first supporting stand 12 has a substantially same height as that of the upper surface 132 of the second supporting stand 13 as shown in FIG. 1.

Preferably, the adhesive 30 is an electrically conductive thermoset resin.

The cover 40 is disposed on the surrounding wall 14 to seal the inner space in which the piezoelectric resonator 20 is disposed.

As shown in FIGS. 1 and 2, the adhesive 30 is bonded not only to the upper surfaces 122, 132 of the first and second supporting stands 12, 13, but also to the first and second inner surfaces 123, 133 of the first and second supporting stands 12, 13 and the top surface 11 of the base 10. Accordingly, the mounting part 21 of the piezoelectric resonator 20 is provided with a relatively strong adhesion with the base 10 and the first and second supporting stands 12, 13.

As shown in FIG. 1, the cover 40 is fixed to a top side of the surrounding wall 14 using a solder 141. The solder 141 is made of tungsten plated with gold in this embodiment. The cover 40 is preferably made of KOV alloy (nickel-cobalt-iron alloy). In detail, after the inner space is filled with inert gas or is vacuumed, the cover 40 is pressed to the base 10 using an electric roller (not shown) that is provided with current from an external power source. Thereafter, the current passes to the cover 40 through the electric roller, and thus heat is generated in the cover 40 due to contact resistance of the cover 40. The heat in the cover 40 melts the solder 141 so as to sealingly bond the cover 40 to the base 10 using the solder 141. Accordingly, sealing of the inner space is completed.

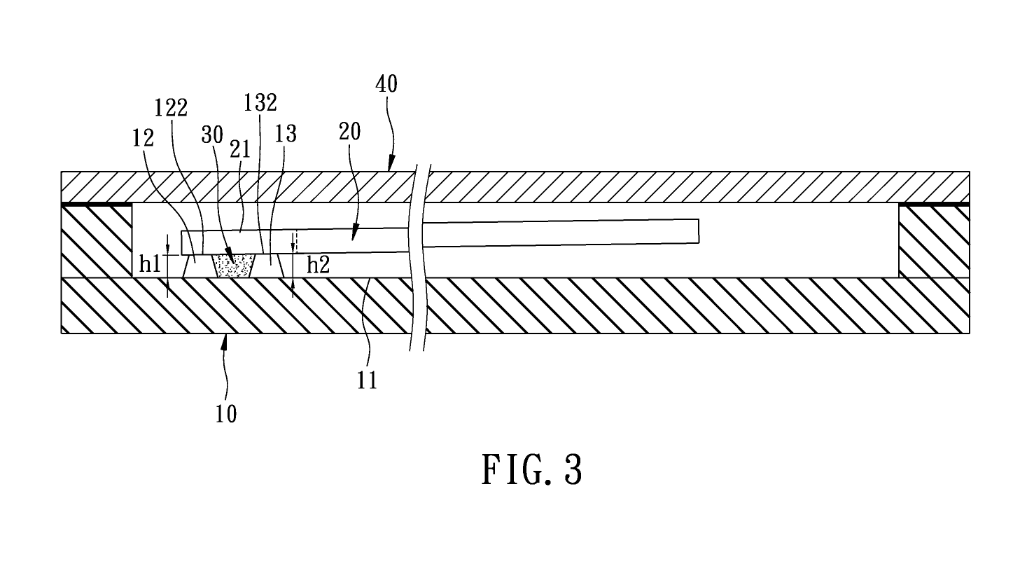

Referring to FIG. 3, the piezoelectric device of the second preferred embodiment according to this invention has a structure similar to that of the first preferred embodiment except that the upper surface 122 of the first supporting stand 12 is lower than the upper surface 132 of the second supporting stand 13. That is, the height (h1) of the first supporting stand 12 from the top surface 11 is shorter than the height (h2) of the second supporting stand 13 from the top surface 11. Thus, the piezoelectric resonator 20 is tilted with respect to the top surface 11 and is gradually distant from the top surface 11 from the outer section 211 to the resonant arm 22. Accordingly, when the piezoelectric device is dropped, collision between the resonant arm 22 of the piezoelectric resonator 20 and the top surface 11 of the base 10 might be avoided.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A piezoelectric device comprising:
a base having a top surface, and first and second marginal ends that are oppositely disposed;
a first supporting stand protruding from said top surface of said base;
a second supporting stand protruding from said top surface of said base and spaced apart from said first supporting stand;
an adhesive applied to upper surfaces of said first and second supporting stands and filled between said first and second supporting stands; and
a piezoelectric resonator including a mounting part which has an outer section adhesively bonded to said upper surface of said first supporting stand, an inner section adhesively bonded to said upper surface of said second supporting stand, and a middle section disposed between said outer and inner sections and bonded to a top surface of said adhesive, and a resonant arm extending from said inner section toward said second marginal end in a cantilever fashion.

2. The piezoelectric device of claim 1, wherein said adhesive is an electrically conductive thermoset resin.

3. The piezoelectric device of claim 1, wherein said upper surface of said first supporting stand is lower than that of said second supporting stand.

4. The piezoelectric device of claim 1, wherein said upper surface of said first supporting stand has a substantially same height as that of said second supporting stand.

5. The piezoelectric device of claim 1, wherein said top surface of said base further has a pair of longitudinal marginal ends each interconnecting said first and second marginal ends, said first and second supporting stands being disposed between said pair of longitudinal marginal ends.

6. The piezoelectric device of claim 5, wherein said base further has a surrounding wall extending upwardly from said first and second marginal ends and said longitudinal marginal ends of said top surface of said base, said surrounding wall and said top surface of said base cooperatively defining an inner space in which said piezoelectric resonator is disposed, said piezoelectric device further comprising a cover disposed to seal said inner space.

7. The piezoelectric device of claim 1, wherein said resonant arm is a forked arm.
